(19) United States
(12) Patent Application Publication
(10) Pub. No.: US 2008/0202581 A1
(43) Pub. Date: Aug. 28, 2008

(54) Photovoltaic cell with reduced hot-carrier cooling

(75) Inventor: Krzysztof Kempa, Billerica, MA (US)

Correspondence Address: FOLEY AND LARDNER LLP;SUITE 500, 3000 K STREET NW, WASHINGTON, DC, 20007, US

(73) Assignee: Solasta, Inc.

(21) Appl. No.: 12/068,745

(22) Filed: Feb. 11, 2008

Related U.S. Application Data
(60) Provisional application No. 60/900,709, filed on Feb. 12, 2007.

(51) Int. Cl. H01L 31/04; H01L 21/00

(52) U.S. Cl. 136/252; 438/98; 977/742; 977/774; 977/762; 257/E21.001

(57) ABSTRACT

A photovoltaic cell includes a first electrode, a first nanoparticle layer located in contact with the first electrode, a second electrode, a second nanoparticle layer located in contact with the second electrode, and a thin film photovoltaic material located between and in contact with the first and the second nanoparticle layers.

### CROSS-REFERENCE TO RELATED PATENT APPLICATIONS

The present application claims benefit of U.S. provisional application 60/900,709, filed Feb. 12, 2007, which is incorporated herein by reference in its entirety.

### BACKGROUND

The present invention relates generally to the field of photovoltaic or solar cells and more specifically to photovoltaic cells containing nanoparticle layers and/or nanocrystalline photovoltaic material films.

In prior art hot-carrier photovoltaic (PV) cells (also known as hot-carrier solar cells), electron-electron interactions at an interface between an electrode and the PV material causes undesirable cooling of the hot electrons in the PV cell and a corresponding loss of the PV cell energy conversion efficiency.

### SUMMARY

An embodiment of the present invention provides a photovoltaic cell includes a first electrode, a first nanoparticle layer located in contact with the first electrode, a second electrode, a second nanoparticle layer located in contact with the second electrode, and a photovoltaic material located between and in contact with the first and the second nanoparticle layers.

### BRIEF DESCRIPTION OF THE DRAWINGS

FIGS. 1A and 1B are schematic three dimensional views of PV cells according to embodiments of the invention.

FIG. 2 is a schematic three dimensional view of a PV cell array according to an embodiment of the invention.

FIG. 3A is a schematic top view of a multichamber apparatus for forming the PV cell array according to an embodiment of the invention.

FIGS. 3B-3G are side cross sectional views of steps in a method of forming the PV cell array in the apparatus of FIG. 3A.

FIG. 4A is a side cross sectional schematic view of an integrated multi-level PV cell array. FIG. 4B is a circuit schematic of the array.

FIG. 5 is a transmission electron microscope (TEM) image of a carbon nanotube (CNT) conformally-coated with CdTe quantum dot (QD) nanoparticles.

### DETAILED DESCRIPTION OF THE EMBODIMENTS

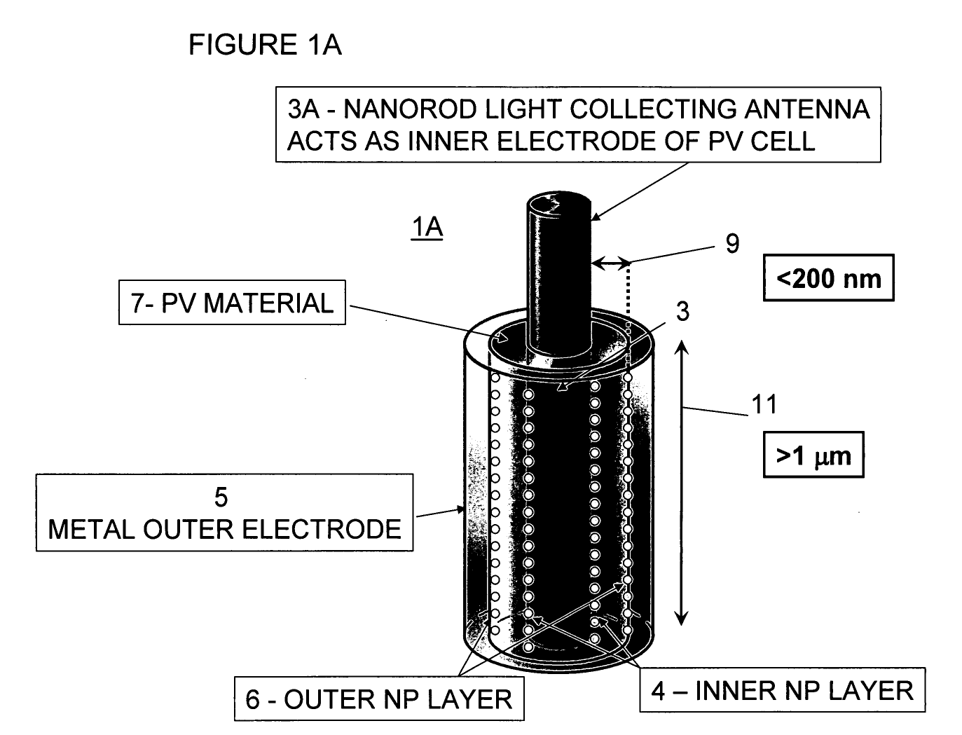

FIGS. 1A and 1B illustrate photovoltaic cells 1A and 1B according to respective first and second embodiments of the invention. Both cells 1A, 1B contain a first or inner electrode 3, a second or outer electrode 5, and a photovoltaic (PV) material 7 located between the first and the second electrodes. In cell 1B shown in FIG. 1B, the PV material 7 is also in electrical contact with the electrodes 3, 5. The width 9 of the photovoltaic material 7 in a direction from the first electrode 3 to the second electrode 5 (i.e., left to right in FIGS. 1A and 1B) is less than about 200 nm, such as 100 nm or less, preferably between 10 and 20 rim. The height 11 of the photovoltaic material (i.e., in the vertical direction in FIGS. 1A and 1B) in a direction substantially perpendicular to the width of the photovoltaic material is at least 1 micron, such as 2 to 30 microns, for example 10 microns. The term “substantially perpendicular” includes the exactly perpendicular direction for hollow cylinder shaped PV material 7, as well as directions which deviate from perpendicular by 1 to 45 degrees for a hollow conical shaped PV material which has a wider or narrower base than top. Other suitable PV material dimensions may be used.

The width 9 of the PV material 7 preferably extends in a direction substantially perpendicular to incident solar radiation that will be incident on the PV cell 1A, 1B. In FIGS. 1A and 1B, the incident solar radiation (i.e., sunlight) is intended to strike the PV material 7 at an angle of about 70 to 110 degrees, such as 85-95 degrees, with respect to the horizontal width 9 direction. The width 9 is preferably sufficiently thin to substantially prevent phonon generation during photogenerated charge carrier flight time in the photovoltaic material to the electrode(s). In other words, the PV material 7 width 9 must be thin enough to transport enough charge carriers to the electrode(s) 3 and/or 5 before a significant number of phonons are generated. Thus, when the incident photons of the incident solar radiation are absorbed by the PV material and are converted to charge carriers (electrons, holes and/or excitons), the charge carriers should reach the respective electrode(s) 3, 5 before a significant amount of phonons are generated (which convert the incident radiation to heat instead of electrical charge carriers which provide a photogenerated electrical current). For example, it is preferred that at least 40%, such as 40-80%, for example 40-100% of the incident photons are converted to a photogenerated charge carriers which reach a respective electrode and create a photogenerated electrical current instead of generating phonons (i.e., heat). A width 9 of about 10 nm to about 20 nm for the examples shown in FIGS. 1A and 1B is presumed to be small enough to prevent generation of a significant number of phonons. Preferably, the width 9 is sufficiently small to substantially prevent carrier (such as electron and/or hole) energy loss due to carrier recombination and/or scattering. For example, for amorphous silicon, this width is less than about 200 nm. The width may differ for other materials.

The height 11 of the photovoltaic material 7 is preferably sufficiently thick to convert at least 90%, such as 90-95%, for example 90-100% of incident photons in the incident solar radiation to charge carriers. Thus, the height 11 of the PV material 7 is preferably sufficiently thick to collect the majority of solar radiation (i.e., to convert a majority of the photons to photogenerated charge carriers) and allowing 10% or less, such as 0-5% of the incident solar radiation to reach or exit out of the bottom of the PV cell (i.e., to reach the substrate below the PV cell). The height 11 is preferably sufficiently large to photovoltaically absorb at least 90%, such as 90-100% of photons in the 50 nm to 2000 nm wavelength range, preferably in the 400 nm to 1000 nm range. Preferably, the height 11 is greater than the longest photon penetration depth in the semiconductor material. Such height is about 1 micron or greater for amorphous silicon. The height may differ for other materials. Preferably, the height 11 is at least 10 times greater, such as at least 100 times greater, such as 1,000 to 10,000 times greater than the width 9.

The first electrode 3 preferably comprises an electrically conducting nanorod, such as a nanofiber, nanotube or nanowire. For example, the first electrode 3 may comprise an electrically conductive carbon nanotube, such as a metallic multi walled carbon nanotube, or an elemental or alloy metal nanowire, such as molybdenum, copper, nickel, gold, or palladium nanowire, or a nanofiber comprising a nanoscale rope of carbon fibrous material having graphitic sections. The nanorod may have a cylindrical shape with a diameter of 2 to 200 nm, such as 30 to 150 nm, for example 50 nm, and a height of 1 to 100 microns, such as 10 to 30 microns. If desired, the first electrode 3 may also be formed from a conductive polymer material. Alternatively, the nanorod may comprise an electrically insulating material, such as a polymer material, which is covered by an electrically conductive shell to form the electrode 3. For example, an electrically conductive layer may be formed over a substrate such that it forms a conductive shell around the nanorod to form the electrode 3. The polymer nanorods, such as plastic nanorods, may be formed by molding a polymer substrate in a mold to form the nanorods on one surface of the substrate or by stamping one surface of the substrate to form the nanorods.

The photovoltaic material 7 surrounds at least a lower portion of the nanorod electrode 3, as shown in FIGS. 1A and 1B. The PV material 7 may comprise any suitable thin film semiconductor material which is able to produce a voltage in response to irradiation with sunlight. For example, the PV material may comprise a bulk thin film of amorphous, single crystal or polycrystalline inorganic semiconductor materials, such as silicon (including amorphous silicon), germanium or compound semiconductors, such Ge, SiGe, PbSe, PbTe, SnTe, SnSe, Bi₂Te₃, Sb₂Te₃, PbS, Bi₂Se₃, GaAs, InAs, InSb, CdTe, CdS or CdSe as well as ternary and quaternary combinations thereof. It can also be a layer of semiconductor nanoparticles, such as quantum dots. The PV material film 7 may comprise one or more layers of the same or different semiconductor material. For example, the PV material film 7 may comprise two different conductivity type layers doped with opposite conductivity type (i.e., p and n) dopants to form a pn junction. This forms a pn junction type PV cell. If desired, an intrinsic semiconductor region may be located between p-type and n-type regions to form a p-i-n type PV cell. Alternatively, the PV material film 7 may comprise two layers of different semiconductor materials having the same or different conductivity type to form a heterojunction. Alternatively, the PV material film 7 may comprise a single layer of material to form a Schottky junction type PV cell (i.e., a PV cell in which the PV material forms a Schottky junction with an electrode without necessarily utilizing a pn junction).

Organic semiconductor materials may also be used for the PV material 7. Examples of organic materials include photoactive polymers (including semiconducting polymers), organic photoactive molecular materials, such as dyes, or a biological photoactive materials, such as biological semiconductor materials. Photoactive means the ability to generate charge carriers (i.e., a current) in response to irradiation by solar radiation. Organic and polymeric materials include polyphenylene vinylene, copper phthalocyanine (a blue or green organic pigment) or carbon fullerenes. Biological materials include proteins, rhodonines, or DNA (e.g. deoxyguanosine, disclosed in Appl. Phys. Lett. 78, 3541 (2001) incorporated herein by reference).

The second electrode 5 surrounds the photovoltaic material 7 to form the so-called nanocoax. The electrode 5 may comprise any suitable conductive material, such as a conductive polymer or an elemental metal or a metal alloy, such as copper, nickel, aluminum or their alloys. Alternatively, the electrode 5 may comprise an optically transmissive and electrically conductive material, such as a transparent conductive oxide (TCO), such as indium tin oxide, aluminum zinc oxide or indium zinc oxide.

The PV cells 1A, 1B are shaped as so-called nanocoaxes comprising concentric cylinders in which the electrode 3 comprises the inner or core cylinder, the PV material 7 comprises the middle hollow cylinder around electrode 3, and the electrode 5 comprises the outer hollow cylinder around the PV material 7. As noted above, the width 9 of the semiconductor thin film PV material is preferably on the order of 10-20 nm to assure that the charge carriers (i.e., electrons and holes) excited deeply into the respective conduction and valence bands do not cool down to band edges before arriving at the electrodes. The nanocoax comprises a subwavelength transmission line without a frequency cut-off which can operate with PV materials having a 10-20 nm width.

Preferably, but not necessarily, an upper portion of the nanorod 3 extends above the top of photovoltaic material 7 and forms an optical antenna 3A for the photovoltaic cell 1A, 1B. The term “top” means the side of the PV material 7 distal from the substrate upon which the PV cell is formed. Thus, the nanorod electrode 3 height is preferably greater than the height 11 of the PV material 7. Preferably, the height of the antenna 3A is greater than three times the diameter of the nanorod 3. The height of the antenna 3A may be matched to the incident solar radiation and may comprise an integral multiple of ½ of the peak wavelength of the incident solar radiation (i.e., antenna height=(n/2)×530 nm, where n is an integer). The antenna 3A aids in collection of the solar radiation. Preferably, greater than 90%, such as 90-100% of the incident solar radiation is collected by the antenna 3A.

In an alternative embodiment, the antenna 3A is supplemented by or replaced by a nanohorn light collector. In this embodiment, the outer electrode 5 extends above the PV material 7 height 11 and is shaped roughly as an upside down cone for collecting the solar radiation.

In another alternative embodiment, the PV cell 1A has a shape other than a nanocoax. For example, the PV material 7 and/or the outer electrode 5 may extend only a part of the way around the inner electrode 3. Furthermore, the electrodes 3 and 5 may comprise plate shaped electrodes and the PV material 7 may comprise thin and tall plate shaped material between the electrodes 3 and 5. Furthermore, the PV cell 1A may have a width 9 and/or height 11 different from those described above.

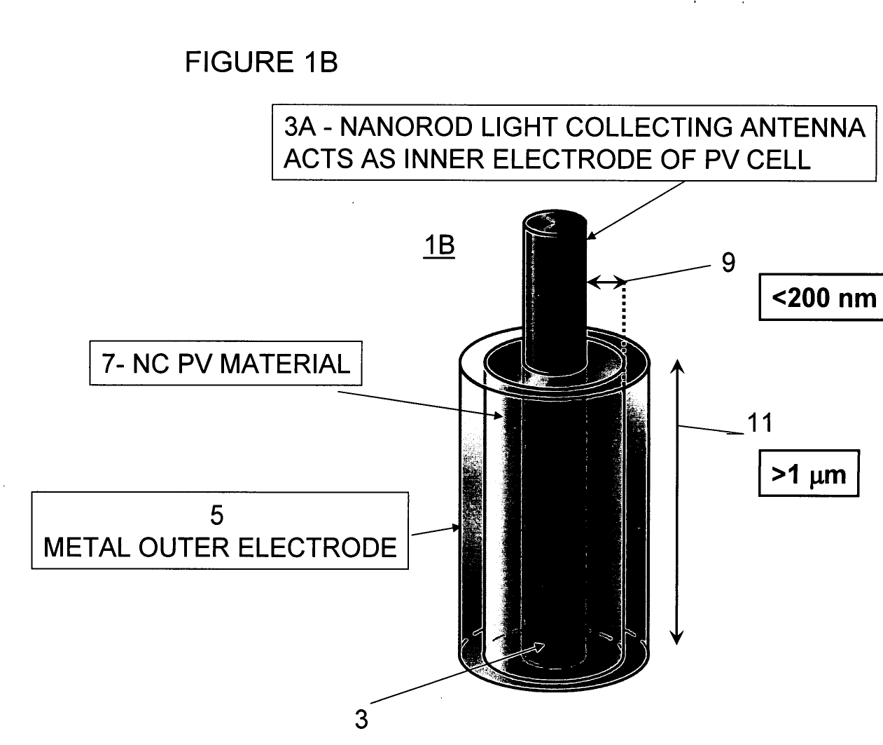

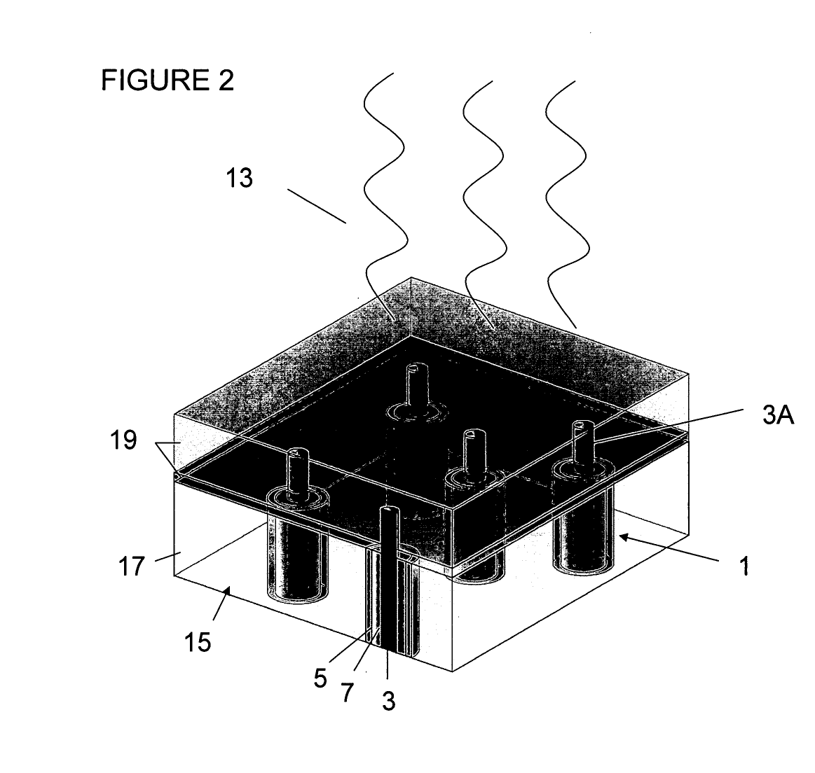

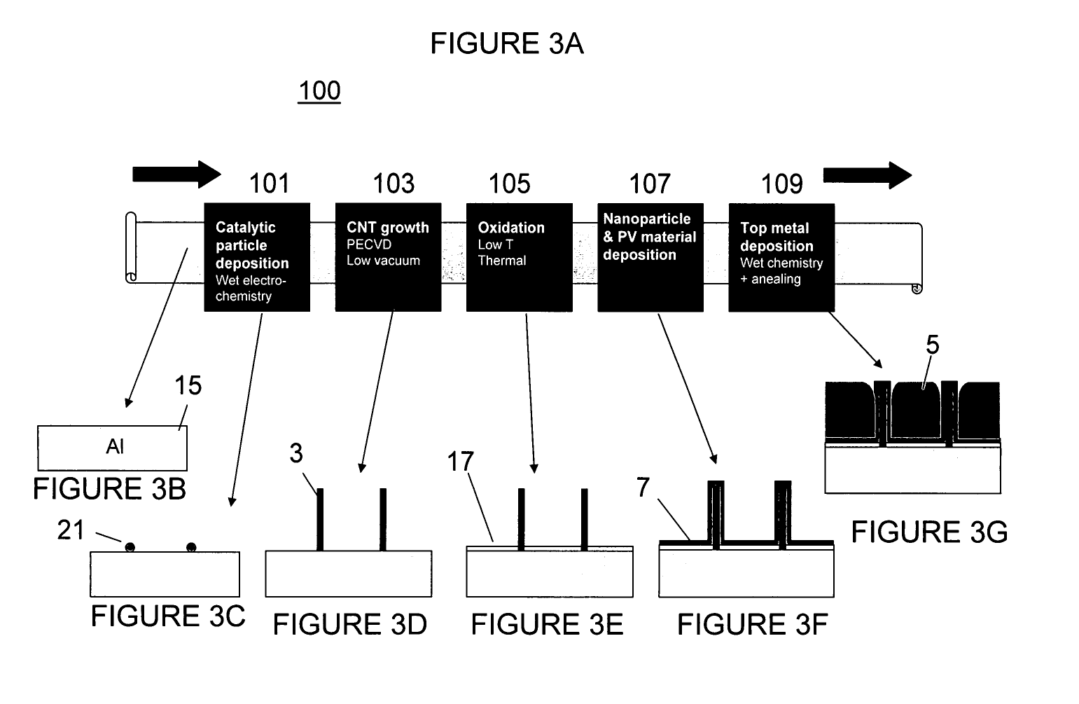

FIG. 2 illustrates an array of nanocoax PV cells 1 in which the antenna 3A in each cell 1 collects incident solar radiation, which is schematically shown as lines 13. As shown in FIGS. 2, 3B, 3D and 3G, the nanorod inner electrodes 3 may be formed directly on a conductive substrate 15, such as a steel or aluminum substrate. In this case, the substrate acts as one of the electrical contacts which connects the electrodes 3 and PV cells 1 in series. For a conductive substrate 15, an optional electrically insulating layer 17, such as silicon oxide or aluminum oxide, may be located between the substrate 15 and each outer electrode 5 to electrically isolate the electrodes 5 from the substrate 15, as shown in FIG. 3E. The insulating layer 17 may also fill the spaces between adjacent electrodes 5 of adjacent PV cells 1, as shown in FIG. 2. Alternatively, if the PV material 7 covers the surface of the substrate 15 as shown in FIG. 3F, then the insulating layer 17 may be omitted. In another alternative configuration, as shown in FIG. 3G, the entire lateral space between the PV cells may be filled with the electrode 5 material if it is desired to connect all electrodes 5 in series. In this configuration, the electrode 5 material may be located above the PV material 7 which is located over the substrate in a space between the PV cells. If desired, the insulating layer 17 may be either omitted entirely or it may comprise a thin layer located below the PV material as shown in FIG. 3G. One electrical contact (not shown for clarity) is made to the outer electrodes 5 while a separate electrical contact is connected to inner electrodes through the substrate 15. Alternatively, an insulating substrate 15 may be used instead of a conductive substrate, and a separate electrical contact is provided to each inner electrode 3 below the PV cells. In this configuration, the insulating layer 17 shown in FIG. 3G may be replaced by an electrically conductive layer. The electrically conductive layer 17 may contact the base of the inner electrodes 3 or it may cover each entire inner electrode 3 (especially if the inner nanorods are made of insulating material). If the substrate 15 comprises an optically transparent material, such as glass, quartz or plastic, then nanowire or nanotube antennas may be formed on the opposite side of the substrate from the PV cell. In the transparent substrate configuration, the PV cell may be irradiated with solar radiation through the substrate 15. An electrically conductive and optically transparent layer 17, such as an indium tin oxide, aluminum zinc oxide, indium zinc oxide or another transparent, conductive metal oxide may be formed on the surface of a transparent insulating substrate to function as a bottom contact to the inner electrodes 3. Such conductive, transparent layer 17 may contact the base of the inner electrodes 3 or it may cover the entire inner electrodes 3. Thus, the substrate 15 may be flexible or rigid, conductive or insulating, transparent or opaque to visible light.

Preferably, one or more insulating, optically transparent encapsulating and/or antireflective layers 19 are formed over the PV cells. The antennas 3A may be encapsulated in one or more encapsulating layer(s) 19. The encapsulating layer(s) 19 may comprise a transparent polymer layer, such as EVA or other polymers generally used as encapsulating layers in PV devices, and/or an inorganic layer, such as silicon oxide or other glass layers.

In the first embodiment of the present invention, the PV cell contains at least one nanoparticle layer between an electrode and the thin film semiconductor PV material 7. Preferably, a separate nanoparticle layer is located between the PV material film 7 and each electrode 3, 5. As shown in FIG. 1A, an inner nanoparticle layer 4 is located in contact with the inner electrode 3 and an outer nanoparticle layer 6 is located in contact with the outer electrode 5. The thin film photovoltaic material 7 is located between and in contact with the inner 4 and the outer 6 nanoparticle layers. Specifically, the inner nanoparticle layer 4 surrounds at least a lower portion of the nanorod electrode 3, the photovoltaic material film 7 surrounds the inner nanoparticle layer 4, the outer nanoparticle layer 6 surrounds the photovoltaic material film 7, and the outer electrode 5 surrounds the outer nanoparticle layer 6 to form the nanocoax. Thus, the nanoparticle layers 4, 6 are located at the interfaces between the PV material film 7 and the respective electrodes 3, 5.

The nanoparticles in layers 4 and 6 may have an average diameter of 2 to 100 nm, such as 10 to 20 nm. Preferably, the nanoparticles comprise semiconductor nanocrystals or quantum dots, such as silicon, germanium or other compound semiconductor quantum dots. However, nanoparticles of other materials may be used instead. The nanoparticle layers 4, 6 have a width of less than 200 nm, such as 2 to 30 nm, including 5 to 20 nm for example. For example, the layers 4, 6 may have a width of less than three monolayers of nanoparticles, such as one to two monolayers of nanoparticles, to allow resonant charge carrier tunneling through the nanoparticle layers from the photovoltaic material film 7 to the respective electrode 3, 5. The nanoparticle layers 4, 6 prevent or reduce the hot carrier cooling by the electrodes. In other words, the nanoparticle layers 4, 6 prevent or reduce electron-electron interactions across the interfaces between the electrodes and the PV material. The prevention or reduction of cooling reduces heat generation and increases the PV cell efficiency.

In another embodiment of the invention, each nanoparticle layer 4, 6 contains at least two sets of nanoparticles having at least one of a different average diameter and/or a different composition. For example, nanoparticle layer 4 may contain a first set of larger diameter nanoparticles and a second set of smaller diameter nanoparticles. Alternatively, the first set may contain silicon nanoparticles and the second set may contain germanium nanoparticles. Each set of nanoparticles is tailored to prevent or reduce the hot carrier cooling by the electrodes. There may be more than two sets of nanoparticles, such as three to ten sets. The sets of nanoparticles may be intermixed with each other in the nanoparticle layers 4, 6. Alternatively, each set of nanoparticles may comprise a thin (i.e., 1-2 monolayer thick) separate sublayer in the respective nanoparticle layer 4, 6.

In another embodiment of the invention shown in FIG. 1B, the photovoltaic material 7 comprises a nanocrystalline thin film semiconductor photovoltaic material. In other words, the PV material 7 comprises a thin film of bulk semiconductor material, such as silicon, germanium or compound semiconductor material, that has a nanocrystalline grain structure. Thus, the film has an average grain size of 300 nm or less, such as 100 nm or less, for example 5 to 20 nm. In this embodiment, the nanoparticle layers 4, 6 may be omitted such that the PV material film 7 is located between and in electrical contact with the inner 3 and the outer 5 electrodes. A nanocrystalline thin film may be deposited by chemical vapor deposition, such as LPCVD or PECVD, at a temperature slightly higher than a temperature used to deposit an amorphous film, but lower than a temperature used to deposit a large grain polycrystalline film, such as a polysilicon film. The nanocrystalline grain structure is also believed to reduce the hot carrier cooling by the electrodes and allows for resonant charge carrier tunneling at the electrodes.

FIG. 3A illustrates a multichamber apparatus 100 for making the PV cells and FIGS. 3B-3G illustrate the steps in a method of making the PV cells 1A, 1B according to another embodiment of the invention. As shown in FIGS. 3A and 3B, the PV cells may be formed on a moving conductive substrate 15, such as on an continuous aluminum or steel web or strip which is spooled (i.e., unrolled) from one spool or reel and is taken up onto a take up spool or reel. The substrate 15 passes through several deposition stations or chambers in a multichamber deposition apparatus. Alternatively, a stationary, discreet substrate (i.e., a rectangular substrate that is not a continuous web or strip) may be used.

First, as shown in FIG. 3C, nanorod catalyst particles 21, such as iron, cobalt, gold or other metal nanoparticles are deposited on the substrate in chamber or station 101. The catalyst particles may be deposited by wet electrochemistry or by any other known metal catalyst particle deposition method. The catalyst metal and particle size are selected based on the type of nanorod electrode 3 (i.e., carbon nanotube, nanowire, etc.) that will be formed.

In a second step shown in FIG. 3D, the nanorod electrodes 3 are selectively grown in chamber or station 103 at the nanoparticle catalyst sites by tip or base growth, depending on the catalyst particle and nanorod type. For example, carbon nanotube nanorods may be grown by PECVD in a low vacuum, while metal nanowires may be grown by MOCVD. The nanorod electrodes 3 are formed perpendicular to the substrate 15 surface. Alternatively, the nanorods may be formed by molding or stamping, as described above.

In a third step shown in FIG. 3E, the optional insulating layer 17 is formed on the exposed surface of substrate 15 around the nanorod electrodes 3 in chamber or station 105. The insulating layer 17 may be formed by low temperature thermal oxidation of the exposed metal substrate surface in an air or oxygen ambient, or by deposition of an insulating layer, such as silicon oxide, by CVD, sputtering, spin-on glass deposition, etc. Alternatively, the optional layer 17 may comprise an electrically conductive layer, such as a metal or a conductive metal oxide layer formed by sputtering, plating, etc.

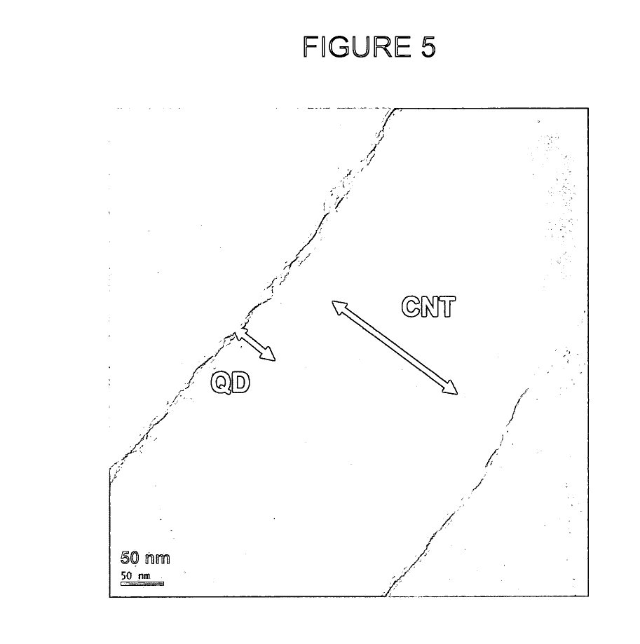

In a fourth step shown in FIG. 3F, nanoparticle layer 4, PV material 7 and nanoparticle layer 6 are formed over and around the nanorod electrodes 3 and over the insulating layer 17 in chamber or station 107. FIG. 5 shows an exemplary TEM image of a carbon nanotube (CNT) conformally-coated with CdTe nanoparticles.

One method of forming the nanoparticle layers 4, 6 comprises separately forming or obtaining commercial semiconductor nanoparticles or quantum dots. The semiconductor nanoparticles are then attached to at least a lower portion of a nanorod shaped inner electrodes 3 to form the inner nanoparticle layer 4. For example, the nanoparticles may be provided from a solution or suspension over the insulating layer 17 and over the electrodes 3. If desired, the nanorod electrodes 3, such as carbon nanotubes, may be chemically functionalized with moieties, such as reactive groups which bind to the nanocrystals using van der Waals attraction or covalent bonding. The photovoltaic material film 7 is then deposited by any suitable method, such as CVD. The second nanoparticle layer 6 is then formed around the film 7 in a similar manner as layer 4.

Alternatively, if the nanocrystalline PV material film 7 of FIG. 1B is used, then the film may be formed by CVD at a temperature range between amorphous and polycrystalline growth temperatures.

In a fifth step shown in FIG. 3G, the outer electrode 5 is formed around the photovoltaic material 7 (or the outer nanoparticle layer 6, if it is present) in chamber or station 109. The outer electrode 5 may be formed by a wet chemistry method, such as by Ni or Cu electroless plating or electroplating following by an annealing step. Alternatively, the electrode 5 may be formed by PVD, such as sputtering or evaporation. The outer electrode 5 and the PV material 7 may be polished by chemical mechanical polishing and/or selectively etched back to planarize the upper surface of the PV cells and to expose the upper portions of the nanorods 3 to form the antennas 3A. If desired, an additional insulating layer may be formed between the PV cells. The encapsulation layer 19 is then formed over the antennas 3A to complete the PV cell array.

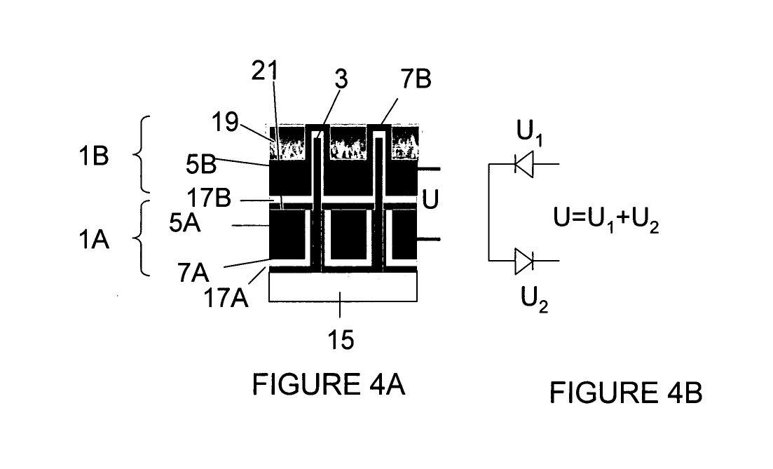

FIG. 4A illustrates a multi-level array of PV cells formed over the substrate 15. In this array, the each PV cell 1A in the lower level shares the inner nanorod shaped electrode 3 with an overlying PV cell 1B in the upper level. In other words, the electrode 3 extends vertically (i.e., perpendicular with respect to the substrate surface) through at least two PV cells 1A, 1B. However, the cells in the lower and upper levels of the array contain separate PV material 7A, 7B, separate outer electrodes 5A, 5B, and separate electrical outputs U1 and U2. Different type of PV material (i.e., different nanocrystal size, band gap and/or composition) may be provided in the cells 1A of the lower array level than in the cells 1A of the upper array level. An insulating layer 21 is located between the upper and lower PV cell levels. The inner electrodes 3 extend through this layer 21. While two levels are shown, three or more device levels may be formed. Furthermore, the inner electrode 3 may extend above the upper PV cell 1B to form an antenna. FIG. 4B illustrates the circuit schematic of the array of FIG. 4A.

A method of operating the PV cell 1A, 1B includes exposing the cell to incident solar radiation 13 propagating in a first direction, as shown in FIG. 2, and generating a current from the PV cell in response to the step of exposing. As discussed above, the width 9 of the PV material 7 between the inner 3 and the outer 5 electrodes in a direction substantially perpendicular to the radiation 13 direction is sufficiently thin to substantially prevent phonon generation during photogenerated charge carrier flight time in the photovoltaic material to at least one of the electrodes and/or to substantially prevent charge carrier energy loss due to charge carrier recombination and scattering. The height 11 of the PV material 7 in a direction substantially parallel to the radiation 13 direction is sufficiently thick to convert at least 90%, such as 90-95%, for example 90-100% of incident photons in the incident solar radiation to charge carriers, such electrons and holes (including excitons) and/or to photovoltaically absorb at least 90%, such as 90-100% of photons in a 50 to 2000 nm, preferably a 400 nm to 1000 nm wavelength range. If the nanoparticle layer(s) 4, 6 of FIG. 1A are present, then resonant charge carrier tunneling preferably occurs through the nanoparticle layer(s) 4, 6 from the photovoltaic material 7 to the respective electrode(s) 3, 5 while the nanoparticle layer(s) prevent or reduce the hot carrier cooling by the electrodes.

If the nanocrystalline PV material 7 of FIG. 1B is present, then the nanocrystalline photovoltaic prevents or reduces hot carrier cooling by the electrodes.

The foregoing description of the invention has been presented for purposes of illustration and description. It is not intended to be exhaustive or to limit the invention to the precise form disclosed, and modifications and variations are possible in light of the above teachings or may be acquired from practice of the invention. The description was chosen in order to explain the principles of the invention and its practical application. It is intended that the scope of the invention be defined by the claims appended hereto, and their equivalents.

What is claimed is:

1. A photovoltaic cell, comprising:
a first electrode;
a first nanoparticle layer located in contact with the first electrode;
a second electrode;
a second nanoparticle layer located in contact with the second electrode; and
a photovoltaic material located between and in contact with the first and the second nanoparticle layers.

2. The cell of claim 1, wherein:
the photovoltaic material comprises a thin film or a nanoparticle material;
a width of the photovoltaic material in a direction from the first electrode to the second electrode is less than about 200 nm; and
a height of the photovoltaic material in a direction substantially perpendicular to the width of the photovoltaic material is at least 1 micron.

3. The cell of claim 2, wherein:
the width of the photovoltaic material is between 10 and 20 nm; and
the height of the photovoltaic material is at least 2 to 30 microns.

4. The cell of claim 1, wherein:
a width of the photovoltaic material in a direction substantially perpendicular to an intended direction of incident solar radiation is sufficiently thin to at least one of substantially prevent phonon generation during photogenerated charge carrier flight time in the photovoltaic material to at least one of the first and the second electrodes or substantially prevent charge carrier energy loss due to charge carrier recombination and scattering; and
a height of the photovoltaic material in a direction substantially parallel to the intended direction of incident solar radiation is sufficiently thick to at least one of convert at least 90% of incident photons in the incident solar radiation to charge carriers or photovoltaically absorb at least 90% of photons in a 50 to 2000 nm wavelength range.

5. The cell of claim 1, wherein:
the first electrode comprises a nanorod;
the first nanoparticle layer surrounds at least a lower portion of the nanorod;
the photovoltaic material surrounds the first nanoparticle layer;
the second nanoparticle layer surrounds the photovoltaic material; and
the second electrode surrounds the second nanoparticle layer to form a nanocoax.

6. The cell of claim 5, wherein the nanorod comprises a carbon nanotube or an electrically conductive nanowire.

7. The cell of claim 6, wherein an upper portion of the nanorod extends above the photovoltaic material and forms an optical antenna for the photovoltaic cell.

8. The cell of claim 1, wherein the photovoltaic material comprises a semiconductor thin film, and the first nanoparticle layer comprises a semiconductor nanoparticle layer having a width of less than three monolayers to allow resonant charge carrier tunneling through the first nanoparticle layer from the photovoltaic material to the first electrode.

9. The cell of claim 1, wherein the first nanoparticle layer contains at least two sets of nanoparticles having at least one of a different average diameter or a different composition.

10. The cell of claim 1, wherein the photovoltaic material comprises silicon and the nanoparticles in the first nanoparticle layer comprise silicon or germanium quantum dots.

11. The cell of claim 1, wherein the first nanoparticle layer prevents or reduces hot carrier cooling by the electrodes.

12. A photovoltaic cell, comprising:
a first electrode;
a second electrode; and
a nanocrystalline thin film semiconductor photovoltaic material located between and in electrical contact with the first and the second electrodes;
wherein:
a width of the photovoltaic material in a direction from the first electrode to the second electrode is less than about 200 nm; and
a height of the photovoltaic material in a direction substantially perpendicular to the width of the photovoltaic material is at least 1 micron.

13. A method of making a photovoltaic cell, comprising:
forming a first electrode;
forming a first nanoparticle layer in contact with the first electrode;
forming a semiconductor photovoltaic material in contact with the first nanoparticle layer;
forming a second nanoparticle layer in contact with the photovoltaic material; and
forming a second electrode in contact with the second nanoparticle layer.

14. The method of claim 13, further comprising:
forming the first electrode perpendicular to a substrate;
forming the first nanoparticle layer around at least a lower portion of the first electrode;
forming the photovoltaic material around the first nanoparticle layer;
forming the second nanoparticle layer around the photovoltaic material; and
forming the second electrode around the second nanoparticle layer.

15. The method of claim 14, wherein: the step of forming the first nanoparticle layer comprises providing semiconductor nanoparticles followed by attaching the provided semiconductor nanoparticles to at least a lower portion of a nanorod shaped first electrode; and the photovoltaic material comprises a thin film or a nanoparticle material.

16. The method of claim 14, wherein the first and the second electrodes and the photovoltaic material are deposited on a moving conductive substrate.

17. The method of claim 16, further comprising forming an array of photovoltaic cells on the substrate.

18. The method of claim 17, further comprising:
spooling a web shaped electrically conductive substrate from a first reel to a second reel;
forming a plurality of metal catalyst particles on the conductive substrate;
growing a plurality of nanorod shaped first electrodes from the metal catalyst particles; and
forming an insulating layer over the substrate between the first electrodes.

19. The method of claim 14, wherein:
a width of the photovoltaic material in a direction from the first electrode to the second electrode is less than about 200 nm; and
a height of the photovoltaic material in a direction substantially perpendicular to the width of the photovoltaic material is at least 1 micron.

20. A method of operating a photovoltaic cell comprising a first electrode, a first nanoparticle layer located in contact with the first electrode, a second electrode, a second nanoparticle layer located in contact with the second electrode, and a photovoltaic material located between and in contact with the first and the second nanoparticle layers, the method comprising:
exposing the photovoltaic cell to incident solar radiation propagating in a first direction; and
generating a current from the photovoltaic cell in response to the step of exposing, such that resonant charge carrier tunneling occurs through the first nanoparticle layer from the photovoltaic material to the first electrode while the first nanoparticle layer prevents or reduces hot carrier cooling by the electrodes.

21. The method of claim 20, wherein:
the photovoltaic material comprises a thin film or a nanoparticle material;
a width of the photovoltaic material between the first and the second electrodes in a second direction substantially perpendicular to the first direction is sufficiently thin to at least one of substantially prevent phonon generation during photogenerated charge carrier flight time in the photovoltaic material to at least one of the first and the second electrodes or substantially prevent charge carrier energy loss due to charge carrier recombination and scattering; and
a height of the photovoltaic material in a direction substantially parallel to the first direction is sufficiently thick to at least one of convert at least 90% of incident photons in the incident solar radiation to charge carriers or photovoltaically absorb at least 90% of photons in a 50 to 2000 nm wavelength range.

22. A method of operating a photovoltaic cell comprising a first electrode, a second electrode, and a thin film nanocrystalline semiconductor photovoltaic material located between and in contact with the first and the second electrodes layers, the method comprising:
exposing the photovoltaic cell to incident solar radiation propagating in a first direction; and
generating a current from the photovoltaic cell in response to the step of exposing, such that the nanocrystalline photovoltaic prevents or reduces the hot carrier cooling by the electrodes.

23. The method of claim 22, wherein:
a width of the photovoltaic material between the first and the second electrodes in a second direction substantially perpendicular to the first direction is sufficiently thin to at least one of substantially prevent phonon generation during photogenerated charge carrier flight time in the photovoltaic material to at least one of the first and the second electrodes or substantially prevent charge carrier energy loss due to charge carrier recombination and scattering; and
a height of the photovoltaic material in a direction substantially parallel to the first direction is sufficiently thick to at least one of convert at least 90% of incident photons in the incident solar radiation to charge carriers or photovoltaically absorb at least 90% of photons in a 50 to 2000 nm wavelength range.
